(19) United States
(12) Patent Application Publication
(10) Pub. No.: US 2003/0184978 A1
(43) Pub. Date: Oct. 2, 2003

(54) Circuit module assembly having an edge-attached vented cover and method for edge-attaching

(76) Inventors: Anthony James LoBianco, Chandler, AZ (US); Kenneth Kaskoun, Phoenix, AZ (US); John Armando Miranda, Chandler, AZ (US)

Correspondence Address: WEISS & MOY PC, 4204 NORTH BROWN AVENUE, SCOTTSDALE, AZ, 85251, US

(21) Appl. No.: 09/915,702

(22) Filed: Jul. 26, 2001

(51) Int. Cl. H05K 5/06

(52) U.S. Cl. 361/728

(57) ABSTRACT

A circuit module assembly having an edge-attached vented cover and method therefor provides packaging for memory modules and other circuit modules. A vented cover is attached to a circuit carrier having electrical connections on a back side and an encapsulated integrated circuit die on a front side. Adhesive film is placed on a lower edge of the vented cover and the vented cover is attached to the carrier by applying pressure. A vent in the vented cover and a gap in the adhesive film provide an escape path for air that would otherwise be entrapped between the vented cover and the carrier. Multiple vents may be used to provide more airflow and vents may be positioned at the sides of the circuit carrier to minimize the impact of gaps in the adhesive.

### FIELD OF THE INVENTION

The present invention relates generally to circuit module packaging, and more specifically, to a method and assembly for attaching a cover to a circuit module carrier.

### BACKGROUND OF THE INVENTION

Removable circuit modules or cards are increasing in use to provide storage and other electronic functions for devices such as digital cameras, personal computing devices and personal digital assistants (PDAs). New uses for memory cards include multi-media cards and secure digital cards.

Assembly of a circuit module typically involves attachment of one or more integrated circuit dies to a carrier or substrate. For multi-media cards, as well as other small form-factor applications, a cover is attached to the carrier to match the outline dimensions specified for the circuit module.

Typically, the covers are manually assembled to the circuit module using a fast-flowing adhesive that is disposed over the inside lower surface of the cover or over the top of an encapsulant covering the dies, and the cover is pressed onto the circuit module. For an automated process, the fast-flowing adhesive is undesirable, as adhesive excess may be ejected from the assembly and adhesive placement is difficult to control.

A low-flow adhesive would produce a superior bond and provide for control of adhesive flow, but use of low-flow adhesive is impractical in the prior-art processes, since the volumes available for the adhesive between the circuit encapsulant and the cover are typically small. The cover may not seat properly with low-flow adhesives, providing undesirable variation in the thickness of the final assemblies and the potential for misalignment.

Therefore, it would be desirable to fabricate circuit modules with a low-flow adhesive, such as an adhesive film or epoxy in an improved automated process.

SUMMARY OF THE INVENTION

A circuit module assembly having an edge-attached cover and method therefor provides packaging for memory modules and other circuit modules. The circuit module assembly comprises one or more integrated circuits for providing an electronic function of the circuit module, a carrier for mounting the integrated circuits, an encapsulation containing the integrated circuits on top of the carrier and a cover for covering the encapsulation.

The cover has an inner ledge adapted for receiving an adhesive disposed between the inner ledge of the cover and a top surface of the carrier. A vent may be incorporated in the inner ledge and the adhesive layer to avoid entrapment of air during assembly of the circuit module.

### BRIEF DESCRIPTION OF THE DRAWINGS

FIG. 1A is a pictorial diagram depicting a top view and FIG. 1B is a pictorial diagram depicting a cross section of a circuit module carrier in accordance with an embodiment of the invention;

FIG. 2A is a pictorial diagram depicting a bottom view and FIG. 2B is a pictorial diagram depicting a cross section of a circuit module cover in accordance with an embodiment of the invention;

FIG. 3A is a pictorial diagram depicting a bottom view and FIG. 3B is a pictorial diagram depicting a cross section of a circuit module in accordance with an embodiment of the invention; and

FIG. 4A is a pictorial diagram depicting a bottom view and FIG. 4B is a pictorial diagram depicting a cross section of a circuit module cover in accordance with an alternative embodiment of the invention.

The invention, as well as a preferred mode of use and advantages thereof, will best be understood by reference to the following detailed description of illustrative embodiments when read in conjunction with the accompanying drawings, wherein like reference numerals indicate like parts throughout.

### DETAILED DESCRIPTION

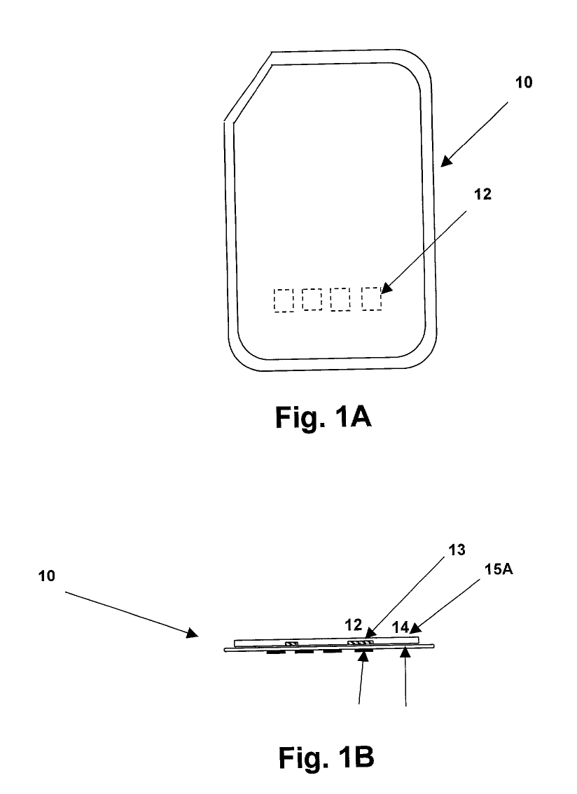

Referring now to FIGS. 1A and 1B, a circuit module carrier 10 in accordance with an embodiment of the invention is depicted. Circuit module carrier 10 is depicted as adapted for use in a circuit module as used in various multimedia memory applications. The present invention is also applicable to cards and modules having other outlines such as secure digital cards and various compact flash memory cards, etc. The present invention applies to peripheral device cards (I/O cards), as well.

A substrate 14 to which integrated circuit dies 13 are attached and circuit contacts 12 are included on the bottom side, is covered by an encapsulant 15 that is bonded to substrate 14, although alternative lids may be used to cover dies 13. Circuit module carrier 10 forms the electronic portion of the circuit module, which must be packaged with a cover which covers the top and edges of circuit module carrier 10 to form a package that conforms with the outlines specified for the particular MMC, SD card, etc.

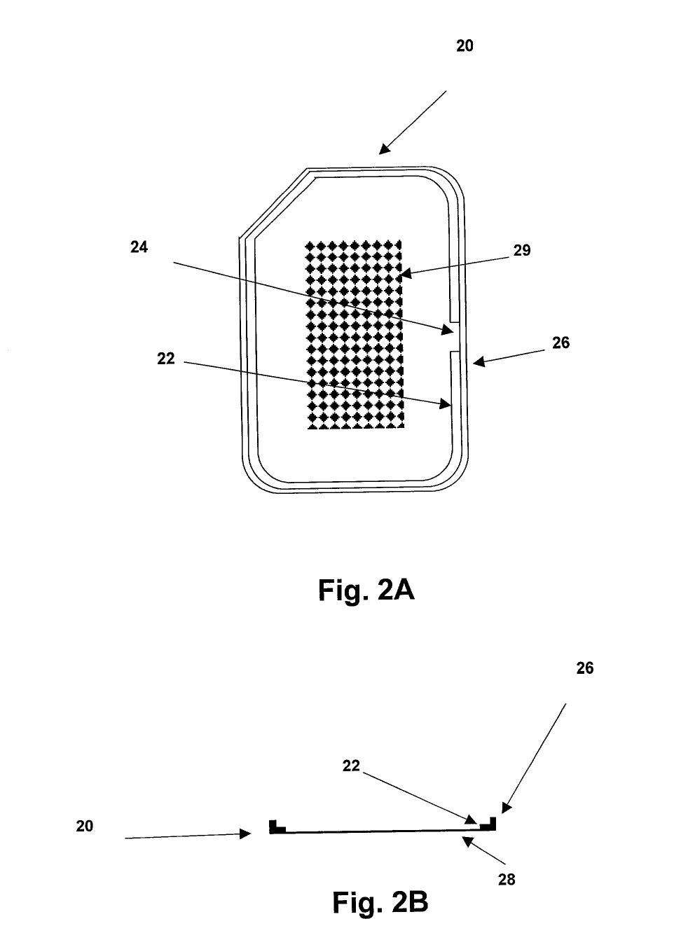

Referring now to FIGS. 2A and 2B, a cover 20 adapted for covering carrier 10 of FIGS. 1A and 1B in accordance with an embodiment of the invention is depicted. A frame portion 26 of cover 20 is used to bond the cover to carrier 10 with an adhesive, which may be an adhesive film, epoxy or other suitable low-flow adhesive known to those skilled in the art of circuit packaging. A ledge 22 is provided to accept the adhesive layer and make contact with the edge of substrate 14 of FIG. 1. A top portion 28 of cover 20 is a very thin wall section. Top portion must be very thin to meet the outline requirements for MMC's, as well as other applications.

The plastic material forming cover 20 is generally an injection molded plastic resin. In order to mold a thin wall cover of this sort, it is generally necessary to vent the mold by a porous mold material, such as PORCERAX, rather than using standard venting techniques. The porous molding material relieves pressure within the mold, permitting thin plastic structures to be made in a fast molding process, without the use of vents that would disrupt the surface of the removable housing and permitting the molten resin to flow fast enough to fill all of the mold features. The mold may be made with PORCERAX section in mold walls forming top portion 28, which will permit air to escape through the mold walls and permit the flow lines forming top portion to meet quickly before the material sets. A housing made by the above-described mold may be identified by rough surfaces in areas 29 that have contacted the PORCERAX portions of the mold.

A vent 24 is molded in ledge 22 and adhesive is not placed in the area of vent 24, so that entrapment of air is prevented when cover 20 is assembled with carrier 10 of FIGS. 1A and 1B. If the adhesive material is an adhesive film, the film must be cut to prevent adhesive from entering the area of vent 24, or the vent may fill with adhesive, causing entrapment of air. Vent 24 is not visible after assembly, as substrate 14 will cover it completely, so that internal portions of the final assembly are not visible. A vent location on the long side of cover 20 was chosen to maximize vent area while minimizing the impact of loss of adhesion in the vent area. The midpoint of the side is chosen to minimize the impact of twisting stress, but other locations may be chosen based on mold design and other mechanical considerations. Vent 24 may be used as the gating point for injection molding, with the advantage that excess material at the gating point will disturb seating of carrier 10 within cover 20, since vent 24 is a gap in ledge 22 and therefore excess material at a gating point in vent 24 that extends below the inner surface of top portion 28 will not contact substrate 14.

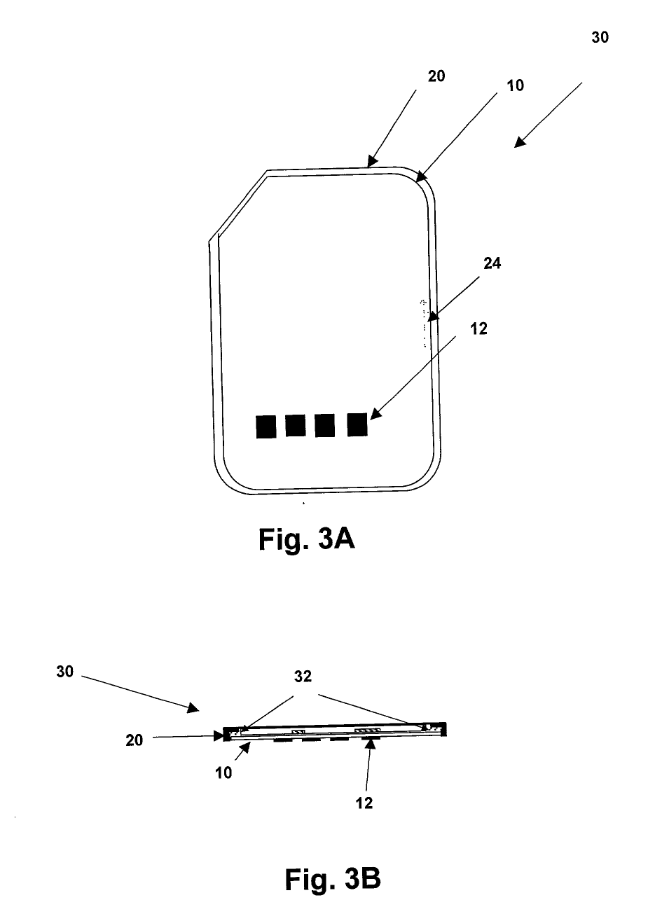

Referring now to FIGS. 3A and 3B, a circuit module assembly 30 in accordance with an embodiment of the invention is depicted. Circuit contacts 12 are visible on the bottom of substrate 14, which is surrounded by the edge of frame portion 26 of cover 20. Adhesive 32 bonds cover 20 to circuit module carrier 10 in the area of ledge 22, excluding the area of vent 24. Vent 24 is obscured by substrate 14, so that internal surfaces of the circuit module assembly 30 are not visible and entry of foreign materials is resisted. But for the action of vent 24, top portion 28 would be deformed by entrapment of air within circuit module assembly 30 and top portion 28 would potentially extend beyond the outline required by mechanical specifications for the MMC. While the drawing of FIG. 3B shows that the top of encapsulant 15A and top portion 28 are in contact, in practice there may be a gap between encapsulant 15A and top portion 28, for example a gap of 3 mils would be practical.

Vent 24 is especially critical in automated assembly processes for attaching cover 20 to carrier 10, since the speed of assembly affects the outflow of air required to prevent deformation of top portion 28. Since top portion is very thin (generally less than 11 mils), any significant back pressure that exists after assembly of the circuit module may cause deformation of top portion 28.

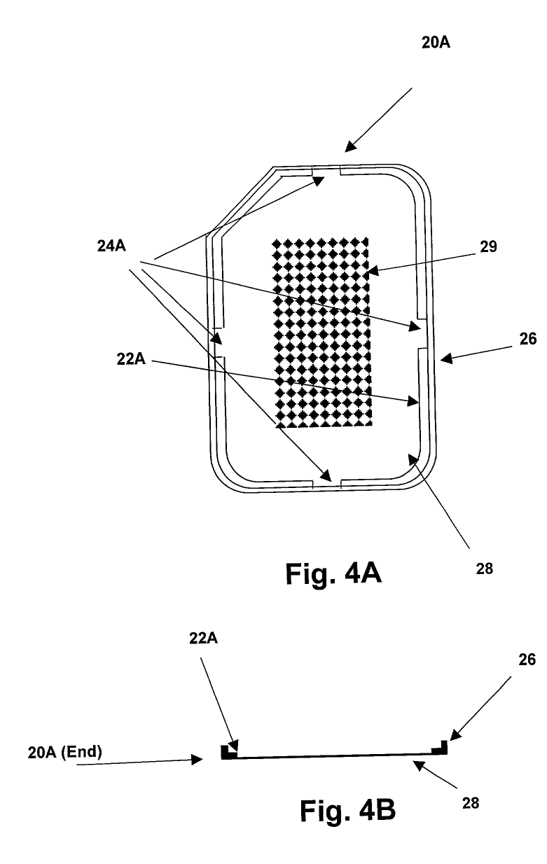

Referring now to FIGS. 4A and 4B, a cover 20A adapted for attachment to the circuit module carrier 10 of FIGS. 1A and 1B in accordance with an alternative embodiment of the invention is depicted. Multiple vents 24A are molded into ledge 22A in this embodiment to provide for greater airflow during assembly. Thus, the size of vents required may be reduced while maintaining sufficient airflow during assembly to prevent entrapment of air and deformation of top portion 28 of cover 20A. Adhesive is not applied in the area of vents 24A and if the adhesive is an adhesive film, the film must be cut to remove adhesive material from the area of vents 24A, or the vents may be blocked by the adhesive.

The above description of embodiments of the invention is intended to be illustrative and not limiting. Other embodiments of this invention will be obvious to those skilled in the art in view of the above disclosure and fall within the scope of the present invention.

What is claimed is:

1. A circuit module, comprising:
at least one integrated circuit for providing an electronic function of the circuit module;
a carrier for mounting the at least one integrated circuit within the circuit module;
an encapsulation containing the at least one integrated circuit on top of the carrier;
a vented cover for covering the encapsulation having a
inner ledge adapted for receiving an adhesive; and
an adhesive layer disposed between the inner ledge of the cover and a top surface of the carrier.

2. The circuit module of claim 1, wherein the adhesive layer is an adhesive film cut to conform to dimensions of the inner ledge.

3. The circuit module of claim 1, wherein the vented cover has a vent for preventing the entrapment of air during assembly of the vented cover to the carrier.

4. The circuit module of claim 3, wherein the vent is covered by the carrier subsequent to attachment of the vented cover to the carrier, so that inner surfaces of the circuit module are not visible subsequent to the attachment.

5. The circuit module of claim 4, wherein the vent is provided by a gap in the inner ledge.

6. The circuit module of claim 5, wherein the gap is positioned substantially near the midpoint of a side of the vented cover, whereby a strength of attachment of the vented cover to the carrier is least affected.

7. The circuit module of claim 5, wherein the adhesive layer is an adhesive film cut to conform to dimensions of the inner ledge excluding the gap.

8. The circuit module of claim 1, wherein the vented cover has multiple vents for preventing the entrapment of air during assembly of the vented cover to the carrier.

9. The circuit module of claim 8, wherein the vents are covered by the carrier subsequent to attachment of the vented cover to the carrier, so that inner surfaces of the circuit module are not visible subsequent to the attachment.

10. The circuit module of claim 9, wherein the vents are provided by gaps in the inner ledge.

11. The circuit module of claim 10, wherein the gaps are each positioned substantially near midpoints of sides of the vented cover, whereby a strength of attachment of the vented cover to the carrier is least affected.

12. A circuit module, comprising:
at least one integrated circuit for providing an electronic function of the circuit module;
a carrier for mounting the at least one integrated circuit within the circuit module;
an encapsulation containing the at least one integrated circuit on top of the carrier;
a vented cover for covering the encapsulation; and
means for attaching the vented cover to the carrier.

13. The circuit module of claim 12, further comprising means for preventing the entrapment of air during assembly of the vented cover to the carrier.

14. A vented cover adapted for attachment to a circuit module, wherein the vented cover comprises:
a top portion; and
a substantially rectangular frame portion disposed around the edges of the top portion, the frame portion having an inner ledge adapted for attaching the top portion to the circuit module.

15. The vented cover of claim 14, wherein the frame portion includes a vent for preventing the entrapment of air during assembly of the vented cover to the circuit module.

16. The vented cover of claim 15, wherein the vent is covered by the a carrier subsequent to attachment of the vented cover to the circuit module, so that inner surfaces of the circuit module are not visible subsequent to the attachment.

17. The vented cover of claim 16, wherein the vent is provided by a gap in the inner ledge.

18. The vented cover of claim 17, wherein the gap is positioned substantially near the midpoint of a side of the frame portion, whereby a strength of attachment of the vented cover to the circuit module is least affected when the vented cover is attached.

19. The vented cover of claim 14, wherein the frame portion includes multiple vents for preventing the entrapment of air during assembly of the vented cover to the circuit module.

20. The vented cover of claim 19, wherein the vents are covered by the carrier subsequent to attachment of the vented cover to the carrier, so that inner surfaces of the circuit module are not visible subsequent to the attachment.

21. The vented cover of claim 20, wherein the vents are provided by gaps in the inner ledge.

22. The vented cover of claim 21, wherein the gaps are each positioned substantially near midpoints of sides of the frame portion, whereby a strength of attachment of the vented cover to the carrier is least affected.

23. The vented cover of claim 14, further comprising means for preventing the entrapment of air during assembly of the vented cover to the circuit module.

24. A method for assembling a circuit module comprising a vented cover having an inner ledge and a carrier, the method comprising:
applying adhesive to the inner ledge of the vented cover; and
pressing the vented cover to the carrier to bond the adhesive.

25. The method of claim 24, wherein the adhesive is an adhesive film and further comprising cutting the adhesive film to conform to the inner ledge of the vented cover.

26. The method of claim 24, further comprising venting air through a vent during the pressing, to prevent entrapment of the air.

27. The method of claim 26, wherein the venting is performed through a gap in the inner ledge.

28. The method of claim 27, wherein the adhesive is an adhesive film and further comprising cutting the adhesive film to conform to the inner ledge of the vented cover and excluding the gap, and wherein the venting is further performed through the gap in the adhesive film.

29. The method of claim 26, wherein the venting is performed through multiple gaps in the inner ledge.

30. The method of claim 29, wherein the adhesive is an adhesive film and further comprising cutting the adhesive film to conform to the inner ledge of the vented cover and excluding the gaps, and wherein the venting is further performed through the gaps in the adhesive film.
